(19) United States
(12) Patent Application Publication
(10) Pub. No.: US 2022/0317394 A1
(43) Pub. Date: Oct. 6, 2022

(54) OPTICAL COMMUNICATION MODULE WITH HEAT-DISSIPATION STRUCTURE

(71) Applicant: SHUNYUN TECHNOLOGY (ZHONG SHAN) LIMITED, Zhongshan (CN)

(72) Inventor: JIE HUANG, Zhongshan City (CN)

(21) Appl. No.: 17/318,353

(22) Filed: May 12, 2021

(30) Foreign Application Priority Data
Mar. 30, 2021 (CN) 202110341542.5

(51) Int. Cl. G02B 6/42; H01S 5/024; H01S 5/0236

(52) U.S. Cl. CPC G02B 6/4271; G02B 6/4206; G02B 6/428; G02B 6/4239; H01S 5/02415; H01S 5/0236

(57) ABSTRACT

An optical communication module with improved heat-dissipating and shock-absorbing properties includes a metal housing; a circuit board disposed in the metal housing; a chip disposed on the circuit board; and a thermoelectric cooling element between the chip and the metal housing. When the chip is operating, current is supplied to the thermoelectric cooling element, and heat generated by the chip is conducted directionally to the metal housing via the thermoelectric cooling element.

### FIELD

The subject matter herein generally relates to optical communications.

### BACKGROUND

Optical communications have low transmission loss, high data confidentiality, total immunity to electromagnetic interference (EMI), and wide bandwidth. The optical communication module receives optical signals and converts the optical signals into electrical signals. The optical communication module can also receive electrical signals and convert same into optical signals, and then transmit the optical signals outwards.

Conventional optical communication modules use a laser chip to emit light beams as signals to an optical fiber. However, the laser chip generates high heat during operation, so a thermal pad is used to connect the laser chip and the metal housing to dissipate the heat of the laser chip. However, current heat dissipation methods do not meet all of the heat dissipation requirements of the current laser chip. In addition, if the metal housing is impacted by an external force, the laser chip may be crushed and damaged, which may cause damage to the optical communication module.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure. It will be appreciated that for simplicity and clarity of illustration, where appropriate, reference numerals have been repeated among the different figures to indicate corresponding or analogous elements.

FIG. 1 is a cross sectional view of an optical communication module in embodiments of the present disclosure.

FIG. 2 is a top view of the optical communication module of FIG. 1 without the metal housing.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The disclosure is illustrated by way of embodiments and not by way of limitation in the figures of the accompanying drawings, in which like references indicate similar elements. It should be noted that references to “an” or “one” embodiment in this disclosure are not necessarily to the same embodiment, and such references mean “at least one.”

The term “connected” is defined as directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

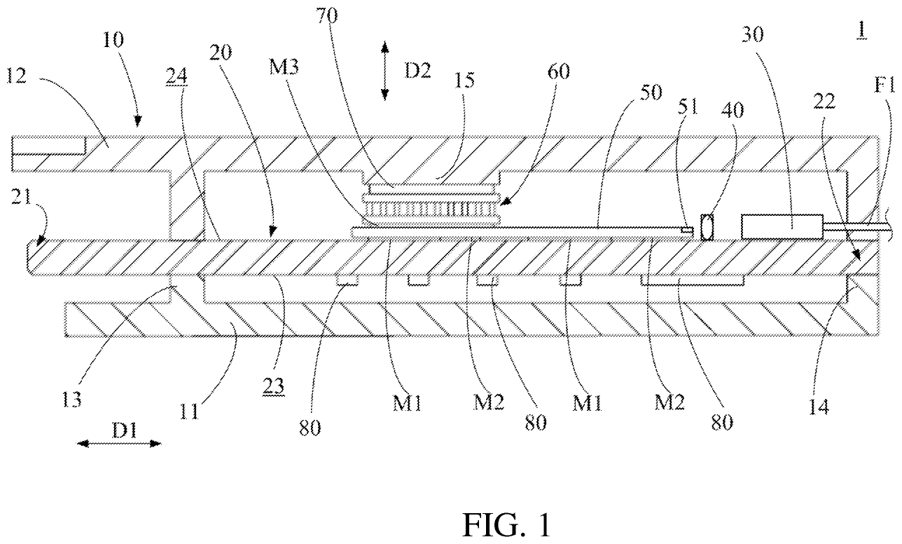

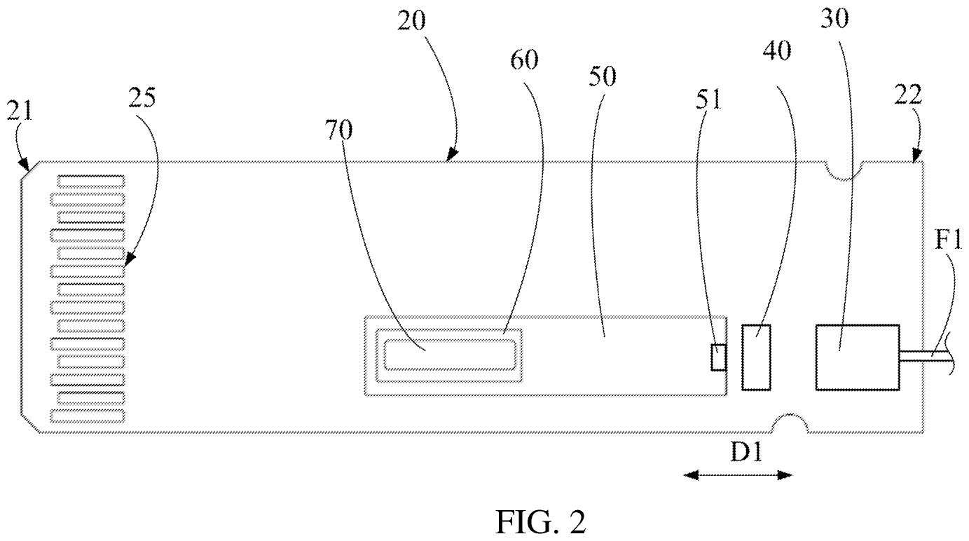

FIG. 1 shows an optical communication module 1 in accordance with an embodiment of the present disclosure. FIG. 2 shows the optical communication module without the metal housing 10. For the purpose of clarity, some components are omitted in FIG. 2. The optical-communication module 1 can be installed in an electronic device so that the electronic device can transmit and receive optical signals. The electronic device can be a computer, a server, or a router, but is not limited thereto. The optical communication module 1 can be an optical transmission module and an optical receiving module, or an optical transceiver module.

The optical transmission module can receive electronic signals from the electronic device, convert the electronic signals to optical signals, and output the optical signals as transmissions via an optical fiber F1. Moreover, the optical receiving module can receive optical signals from the optical fiber F1, convert the optical signals to electronic signals, and transmit the electronic signals to the electronic device. In addition, the optical transceiver module can integrate the functions of the optical transmission module and the optical receiving module so as to covert the electronic signals of the electronic device to the optical signals, and output the optical signals as transmissions via the optical fiber F1.

In the embodiment, the optical communication module 1 may be an optical transmission module, but it is not limited thereto. The optical communication module 1 includes a metal housing 10, a circuit board 20, a fiber array unit 30, a condenser lens 40, a chip 50, a thermoelectric cooling element 60, and a thermal pad 70. The metal housing 10 is an elongated structure, extending in an extension direction D1.

In the embodiment, the metal housing 10 includes a lower cover 11, an upper cover 12, a first wall 13, and a second wall 14. The lower cover 11 and the upper cover 12 are elongated structures, extending in the extension direction D1. The upper cover 12 is disposed on the lower cover 11, and connected to the lower cover 11. The first wall 13 is connected to the lower cover 11 and the upper cover 12, and the second wall 14 is connected to the lower cover 11 and the upper cover 12. In other words, the first wall 13 and the second wall 14 is between the lower cover 11 and the upper cover 12. Moreover, the first wall 13 and the second wall 14 are perpendicular to the lower cover 11 and/or the upper cover 12. The first wall 13 is parallel to the second wall 14.

The circuit board 20 is disposed in the metal housing 10, and located between the lower cover 11 and the upper cover 12. The circuit board 20 is an elongated structure, extending in the extension direction D1. In the embodiment, the first end 21 and the second end 22 of the circuit board 20 can pass through the first wall 13 and the second wall 14. Moreover, the first end 21 of the circuit board 20 protrudes through and beyond the first wall 13. A conductive pad 25 is at the first end 21 of the circuit board 20. The first end 21 can be inserted into a slot of the electronic device, and the conductive pad 25 is electrically connected to the slot of the electronic device. The second end 22 of the circuit board 20 goes through but does not protrude beyond the second wall 14.

The fiber array unit (FAU) 30 is disposed on the circuit board 20, and adjacent to the second wall 14. FAU 30 is connected to the optical fiber F1, and optical fiber F1 passes through the second wall 14. The condenser lens 40 is disposed on the circuit board 20, and between the FAU 30 and the chip 50. In the embodiment, the condenser lens 40 is in contact with the chip 50.

The chip 50 is disposed on the front surface 24 of the circuit board 20 between the first wall 13 and the second wall 14. In the embodiment, the chip 50 and the circuit board 20 may be plate-like structures, and extend perpendicular to an arrangement direction D2. The arrangement direction D2 is perpendicular to the direction D1. In the embodiment, the chip 50 is a laser chip. The laser chip may be a distributed feedback laser. The chip 50 includes a light emitting unit 51, configured to emit a laser beam. The chip 50 drives the light emitting unit 51 to emit a laser beam with optical signals according to the electronic signals transmitted from the electronic device. The laser beam is focused by the condenser lens 40 and falls on the fiber array unit 30. The laser beam enters into the optical fiber F1 via the fiber array unit 30.

The thermoelectric cooling element 60 is disposed on the chip 50 between the chip 50 and the upper cover 12 of the metal housing 10. The thermal pad 70 is disposed on the thermoelectric cooling element 60. The upper cover 12 further includes thermally conductive bumps 15 which are in contact with the thermal pad 70. The thermoelectric cooling element 60, the thermal pad 70, and the thermally conductive bumps 15 may be plate-like structures, and extend perpendicular to the arrangement direction D2. In the embodiment, the circuit board 20, the chip 50, the thermoelectric cooling element 60, the thermal pad 70, and the thermally conductive bumps 15 are arranged in the arrangement direction D2.

In the embodiment, the area of the chip 50 in the extension direction D1 is greater than 1.5 times or 2 times the area of the thermoelectric cooling element 60 in the extension direction D1. In some embodiments, the optical communication module 1 does not include the thermal pad 70 and/or the thermally conductive bumps 15, thus the thermoelectric cooling element 60 is in direct contact with the thermally conductive bumps 15 or with the upper cover 12. Moreover, the thermoelectric cooling element 60 may be adhered to the chip 50 by conductive epoxy M3, improving the conduction efficiency between the chip 50 and the thermoelectric cooling element 60.

In the embodiment, the thermoelectric cooling element 60 may be a thermoelectric cooler device (TEC). The TEC 60 is electrically connected to the chip 50 or the circuit board 20. When the chip 50 is operating, the chip 50 or the circuit board 20 supplies current to the TEC 60, so that the thermoelectric cooling element 60 removes the heat generated by the chip 50 in the arrangement direction D2 to the upper cover 12 of the metal housing 10 through the TEC 60. The efficiency of the chip 50 in dissipating heat to the metal housing 10 is improved by the thermoelectric cooler.

The optical communication module 1 may include electronic elements 80, disposed on the rear surface 23 of the circuit board 20. The electronic elements 80 may be resistances, capacitances, and/or control chips, but not limited thereto. In the embodiment, the TEC 60 dissipates the heat generated by the chip 50 directionally to the upper cover 12, thus protecting the electronic elements 80 on the rear surface 23 of the circuit board 20 from exposure to heat.

In the embodiment, the chip 50 is adhered to the circuit board 20 by soft epoxy glues M1 and hard epoxy glues M2. The soft epoxy glues M1 and the hard epoxy glue M2 are alternately arranged in the arrangement direction D2. Moreover, each of the areas of the soft epoxy glue M1 is greater than each area of the hard epoxy glue M2. In the embodiment, there is a gap created between the chip 50 and the circuit bard 20 by the hard epoxy glue M2 supporting the chip 50, thereby reducing the heat conduction from the chip 50 to the rear surface 23 of the circuit board 20.

In addition, in the embodiment, the chip 50 is adhered to the circuit board 20 by the soft epoxy glue M1. Therefore, when the metal housing 10 is impacted or crushed, the soft epoxy glue M1 provides a buffer function for the chip 50, which in turn protects the chip 50 from damage.

In the present disclosure, the thermoelectric cooling element dissipates the heat generated by the chip directionally, which protects the electronic elements on the rear surface of the circuit board. Moreover, the chip is supported by hard epoxy glue so that there is a gap between the chip and the circuit board, reducing the heat conduction from the chip to the rear surface of the circuit board. In addition, the soft epoxy glue provides a buffer function against damage to the chip.

Many details are often found in the relevant art, thus many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will, therefore, be appreciated that the embodiments described above may be modified within the scope of the claims.

What is claimed is:

1. An optical communication module comprising:
a metal housing;
a circuit board disposed in the metal housing;
a chip disposed on the circuit board; and
a thermoelectric cooling element between the chip and the metal housing;
wherein when the chip is operating, current is supplied to the thermoelectric cooling element, and a heat generated by the chip is conducted to the metal housing via the thermoelectric cooling element.

2. The optical communication module as claimed in claim 1, wherein the chip is adhered to the circuit board by a plurality of soft epoxy glues and a plurality of hard epoxy glues, and the thermoelectric cooling element is adhered to the chip by a conductive epoxy.

3. The optical communication module as claimed in claim 2, wherein the soft epoxy glues and the hard epoxy glues are alternately arranged in an arrangement direction, and an area of each of the soft epoxy glues is greater than an area of each of the hard epoxy glues.

4. The optical communication module as claimed in claim 1, further comprising a plurality of electronic elements disposed on a rear surface of the circuit board, and the chip is disposed on a front surface of the circuit board.

5. The optical communication module as claimed in claim 1, wherein the metal housing further comprises a lower cover and an upper cover, and the circuit board is between the lower cover and the upper cover.

6. The optical communication module as claimed in claim 5, further comprising a thermal pad disposed on the thermoelectric cooling element, wherein the upper cover further comprising a thermally conductive bump contacts with the thermal pad.

7. The optical communication module as claimed in claim 1, wherein the metal housing further comprises a first wall and a second wall, the first wall is connected to the lower cover and the upper cover, the second wall is connected to the lower cover and the upper cover, the circuit board passes through the first wall and the second wall, and the chip is between the first wall and the second wall.

8. The optical communication module as claimed in claim 1, wherein an area of the chip is greater than 1.5 times an area of the thermoelectric cooling element.

9. The optical communication module as claimed in claim 1, further comprising a fiber array unit and a condenser lens, the fiber array unit and the condenser lens are disposed on the circuit board, and the condenser lens is between the chip and the condenser lens.

10. The optical communication module as claimed in claim 9, wherein the chip is a laser chip, and the laser chip is configured to emit a laser beam to the fiber array unit via the condenser lens.
